(19) United States
(12) Patent Application Publication
(10) Pub. No.: US 2024/0327198 A1
(43) Pub. Date: Oct. 3, 2024

(54) ACCELERATION DETECTION DEVICE AND ACCELERATION SENSOR

(71) Applicant: ROHM CO., LTD., Kyoto (JP)

(72) Inventors: Martin Wilfried HELLER, Kyoto (JP); Toma FUJITA, Kyoto (JP)

(73) Assignee: ROHM CO., LTD., Kyoto (JP)

(21) Appl. No.: 18/619,807

(22) Filed: Mar. 28, 2024

(30) Foreign Application Priority Data
Mar. 29, 2023 (JP) 2023-053530

(51) Int. Cl. B81B 3/00; G01P 15/125

(52) U.S. Cl. CPC B81B 3/0027; G01P 15/125; B81B 2201/0235; B81B 2203/0163; B81B 2203/0307; B81B 2203/04; B81B 2203/051

(57) ABSTRACT

An acceleration detection device includes: a substrate including cavity; an anchor mechanically connected to the substrate inside the cavity; a spring mechanically connected to the anchor; a mass mechanically connected to the spring; a first movable electrode mechanically connected to and electrically insulated from the mass; a first fixed electrode mechanically connected to and electrically insulated from the substrate; a pair of second movable electrodes facing each other by being mechanically connected to and electrically insulated from the mass; and a second fixed electrode mechanically connected to and electrically insulated from the substrate to be interposed between the pair of second movable electrodes, the second fixed electrode generating an electrostatic force between the pair of second movable electrodes and the second fixed electrode when a voltage is applied to each of the pair of second movable electrodes and the second fixed electrode.

### CROSS-REFERENCE TO RELATED APPLICATION

This application is based upon and claims the benefit of priority from Japanese Patent Application No. 2023-053530, filed on Mar. 29, 2023, the entire contents of which are incorporated herein by reference.

### TECHNICAL FIELD

The present disclosure relates to an acceleration detection device and an acceleration sensor.

### BACKGROUND

In the related art, a capacitive acceleration sensor is provided that detects an acceleration based on a capacitance that changes depending on a distance between a first electrode and a second electrode which changes as the acceleration is applied.

### BRIEF DESCRIPTION OF DRAWINGS

The accompanying drawings, which are incorporated in and constitute a part of the specification, illustrate embodiments of the present disclosure.

FIG. 1 is a plan view of an acceleration detection device according to an embodiment of the present disclosure.

FIG. 2 is a plan view of a first substrate of the acceleration detection device of FIG. 1.

FIG. 3 is a block diagram of an acceleration sensor including the acceleration detection device of FIG. 1.

FIG. 4 is a flowchart of acceleration calculation performed by an acceleration calculator of FIG. 3.

FIG. 5 is a flowchart of resonance frequency adjustment performed by a resonance frequency passive adjuster of FIG. 3.

FIG. 6 is a block diagram of the acceleration detection device and a resonance frequency active adjuster of FIG. 3.

FIG. 7 is a flowchart of resonance frequency adjustment performed by the resonance frequency active adjuster of FIG. 6.

FIG. 8 is a flowchart for determining and releasing electrode fixation performed by an electrode fixation determiner and releaser of FIG. 3.

FIG. 9 is a flowchart of offset trim performed by an offset trimmer of FIG. 3.

FIG. 10 is a flowchart of self-test performed by a self-tester of FIG. 3.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

An embodiment of the present disclosure will be described below with reference to the accompanying drawings. It should be noted that the following description is in essence merely an example and is not intended to limit the present disclosure, its applications, or its uses. Moreover, the drawings are schematic, and a ratio or the like of each dimension is different from actual one.

### [Structure of Acceleration Detection Device]

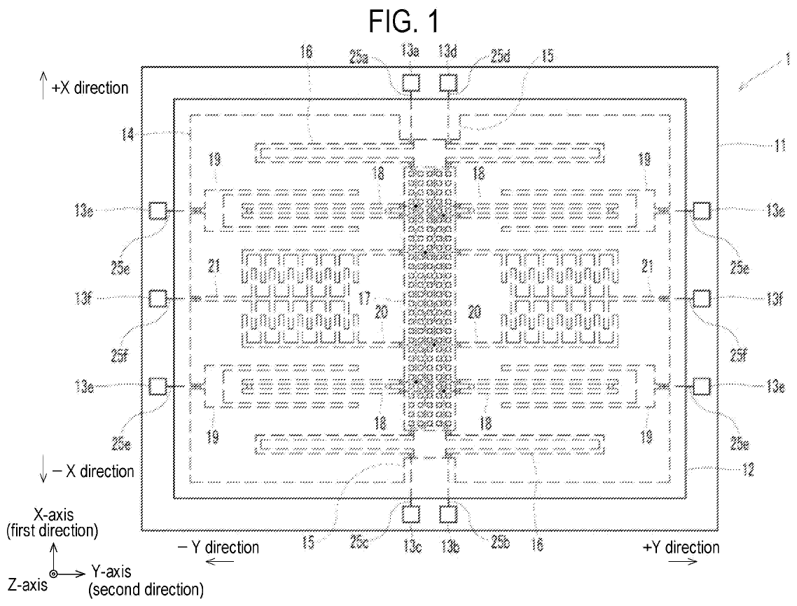

FIG. 1 is a plan view of an acceleration detection device 1 according to an embodiment of the present disclosure. The acceleration detection device 1 includes a first substrate 11 located on the back side in FIG. 1 and a second substrate 12 located on the front side in FIG. 1. The first substrate 11 and the second substrate 12 each have a quadrangular shape extending along a predetermined first direction and a second direction perpendicular to the first direction in a plan view. The second substrate 12 is disposed above the first substrate 11 and is bonded to face each other in a height direction.

In the present embodiment, the first direction is a vertical direction in FIG. 1 and is referred to as an X-axis direction. The second direction is a horizontal direction in FIG. 1 and is referred to as a Y-axis direction. The height direction is a direction along from the front side to the back side of FIG. 1 and is referred to as a Z-axis direction. Further, in FIG. 1, the upper side is referred to as a +X direction, the lower side is referred to as a −X direction, the right side is referred to as a +Y direction, the left side is referred to as a −Y direction, the front side is referred to as a +Z direction, and the back side is referred to as a −Z direction.

In the present embodiment, the first substrate 11 is a base substrate made of silicon, while the second substrate 12 is a lid substrate made of silicon. The first substrate 11 includes electrode pads 13a to 13f which are electrically connected to an electric circuit provided at the first substrate 11, which will be described later and configured to input and output electric signals.

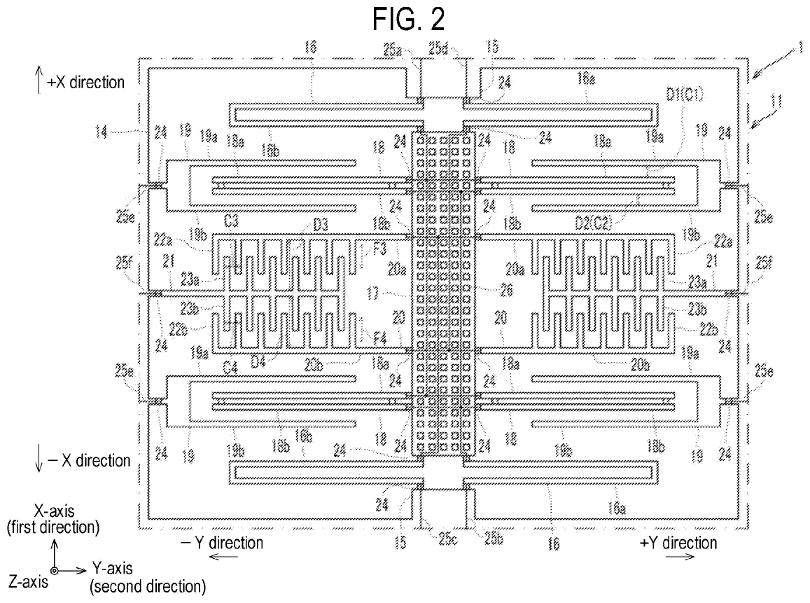

FIG. 2 is a plan view of the first substrate 11 of the acceleration detection device 1 of FIG. 1. The first substrate 11 includes a quadrangular cavity 14 recessed in the −Z direction on a surface on the +Z direction side.

The acceleration detection device 1 includes a pair of anchors 15 provided at an edge of the cavity 14 in the +X direction and an edge of the cavity 14 in the −X direction, respectively. The pair of anchors 15 are each mechanically connected to the first substrate 11 and extend toward an inner side of the cavity 14 in the X-axis direction.

The acceleration detection device 1 includes a pair of springs 16 arranged at an inner side of the cavity 14 than the pair of anchors 15 in the X-axis direction. Each of the pair of springs 16 is mechanically connected to and electrically insulated from the anchor 15, and may be expanded and contracted in the X-axis direction.

In the present embodiment, the pair of springs 16 extend in the Y-axis direction and include a plate spring 16a extending in the +Y direction and a plate spring 16b extending in the −Y direction, but may have other spring shapes such as a coil spring.

The acceleration detection device 1 includes a mass 17 arranged between the pair of springs 16 in the X-axis direction. The mass 17 is mechanically connected to and electrically insulated from the pair of springs 16 and is separated from a bottom of the cavity 14 of the first substrate 11 in the +Z direction. Since the mass 17 is separated from the first substrate 11, the mass 17 may be displaced in the X-axis direction when an acceleration in the X-axis direction is applied.

In the present embodiment, the mass 17 has a rectangular shape extending in the X-axis direction, but may have another shape such as a hexagonal shape.

The acceleration detection device 1 includes four first movable electrodes 18 that are arranged to be spaced apart from each other in the X-axis direction on both sides of the mass 17 in the Y-axis direction. The first movable electrodes 18 are mechanically connected to and electrically insulated from the +X direction side and the −X direction side of the +Y direction side edge of the mass 17 and the +X direction side and the −X direction side of the −Y direction side edge of the mass 17, respectively. The first movable electrodes 18 each extend from the mass 17 in the Y-axis direction and are separated from a bottom of the cavity 14 of the first substrate 11 in the +Z direction. Since the first movable electrodes 18 are each mechanically connected to the mass 17 and separated from the first substrate 11, the first movable electrodes 18 may be displaced together with the mass 17 in the X-axis direction.

In the present embodiment, each of the first movable electrodes 18 includes a pair of flat plate electrodes 18a and 18b that face each other in the X-axis direction and are mechanically connected to and electrically insulated from each other, but may have other electrode shapes such as an interdigital electrode.

The acceleration detection device 1 includes four first fixed electrodes 19 that are arranged to be spaced apart from each other in the X-axis direction at the edges of the cavity 14 on the +Y direction side and the −Y direction side. The first fixed electrodes 19 are mechanically connected to and electrically insulated from the +X direction side and the −X direction side of the +Y direction side edge in the inner side of the first substrate 11 and the +X direction side and the −X direction side of the −Y direction side edge in the inner side of the first substrate 11, respectively. The first fixed electrodes 19 extend from the first substrate 11 in the Y-axis direction and face the first movable electrodes 18 at intervals in the X-axis direction, respectively.

In the present embodiment, the first fixed electrodes 19 each have a pair of flat plate electrodes 19a and 19b that face each other in the X-axis direction so as to sandwich the first movable electrode 18 from both sides in the +X direction and the −X direction, but may have other electrode shapes, such as an interdigital electrode, in accordance with a shape of the first movable electrode 18.

The flat plate electrode 18a of the first movable electrode 18 faces the flat plate electrode 19a of the first fixed electrode 19. The flat plate electrode 18b of the first movable electrode 18 faces the flat plate electrode 19b of the first fixed electrode 19. When the mass 17 is not subjected to an acceleration in the X-axis direction, that is, is located at a zero point which is an initial position, the first movable electrode 18 and the first fixed electrode 19 are arranged such that a distance D1 between the flat plate electrode 18a and the flat plate electrode 19a is equal to a distance D2 between the first flat plate electrode 18b and the flat plate electrode 19b.

The acceleration detection device 1 includes two pairs of second movable electrodes 20 that are arranged to be spaced apart from each other in the X-axis direction between the respective first movable electrodes 18 on both sides of the mass 17 in the Y-axis direction. The two pairs of second movable electrodes 20 each include a +X direction side second movable electrode 20a that is mechanically connected to and electrically insulated from the +X direction side of the mass 17 and extends from the mass 17 in the Y-axis direction, and a −X direction side second movable electrode 20b that is mechanically connected to and electrically insulated from the −X direction side of the mass 17 and extends from the mass 17 in the Y-axis direction. The +X direction side second movable electrode 20a and the −X direction side second movable electrode 20b are separated from the bottom of the cavity 14 of the first substrate 11 in the +Z direction. Since the two pairs of second movable electrodes 20 are each mechanically connected to the mass 17 and separated from the first substrate 11, they may be displaced together with the mass 17 in the X-axis direction.

The acceleration detection device 1 includes two second fixed electrodes 21 arranged on the edge of the cavity 14 in the +Y direction and the edge of the cavity 14 in the −Y direction. The second fixed electrodes 21 are mechanically connected to and electrically insulated from the +Y direction side edge and the −Y direction side edge in the inner side of the first substrate 11, respectively. The second fixed electrodes 21 each extend in the Y-axis direction from the first substrate 11 and are arranged with an interval between the +X direction side second movable electrode 20a and the −X direction side second movable electrode 20b.

In the present embodiment, the +X direction side second movable electrode 20a and the second fixed electrode 21 each include a movable side interdigital electrode 22a and a fixed side interdigital electrode 23a that extend in the X direction and face each other at an interval in the Y-axis direction. Further, the −X direction side second movable electrode 20b and the second fixed electrode 21 each include a movable side interdigital electrode 22b and a fixed side interdigital electrode 23b that extend in the X direction and face each other at an interval in the Y-axis direction.

The first movable electrode 18 and the second movable electrode 20 are each mechanically connected to and electrically insulated from the mass 17 via an isolation joint 24. The mass 17 is mechanically connected to and electrically insulated from the pair of springs 16 via the isolation joint 24. The pair of springs 16 are mechanically connected to and electrically insulated from the pair of anchors 15 via the isolation joint 24. The first fixed electrode 19 and the second fixed electrode 21 are mechanically connected to and electrically insulated from the first substrate 11 via the isolation joint 24.

The isolation joint 24 is made of silicon oxide, which is formed by, for example, forming a trench in the first substrate 11 and thermally oxidizing conductive silicon on both walls of the trench, and mechanically connects and electrically insulates both sides of the isolation joint 24. The isolation joint 24 is separated from the bottom of the cavity 14 of the first substrate 11 in the +Z direction.

A lead 25a is electrically connected to ends of the flat plate electrodes 18a of the four first movable electrodes 18. The lead 25a is electrically connected to the plate spring 16b of the spring 16 on the +X direction side in the mass 17 via a wiring layer (not shown) and is electrically connected to the electrode pad 13a via the plate spring 16b on the +X direction side.

A lead 25b is electrically connected to the ends of the flat plate electrodes 18b of the four first movable electrodes 18. The lead 25b is electrically connected to the plate spring 16a of the spring 16 on the −X direction side in the mass 17 via a wiring layer (not shown) and is electrically connected to the electrode pad 13b via the plate spring 16a on the −X direction side.

A lead 25c is electrically connected to the ends of the two +X direction side second movable electrodes 20a. The lead 25c is electrically connected to the plate spring 16b of the spring 16 on the −X direction side in the mass 17 via a wiring layer (not shown) and is electrically connected to the electrode pad 13c via the plate spring 16b on the −X direction side.

A lead 25d is electrically connected to the ends of the two-X direction side second movable electrodes 20b. The lead 25d is electrically connected to the plate spring 16a of the spring 16 on the +X direction side in the mass 17 via a wiring layer (not shown) and is electrically connected to the electrode pad 13d via the plate spring 16a on the +X direction side.

Leads 25e are electrically connected to the ends of the four first fixed electrodes 19, respectively. The leads 25e are electrically connected to the electrode pads 13e.

Leads 25f are electrically connected to the ends of the two second fixed electrodes 21, respectively. The leads 25f are electrically connected to the electrode pads 13f.

In the present embodiment, the mass 17 has a plurality of holes 26. Bottoms of the plurality of holes 26 are connected to each other by isotropic etching to form the cavity 14. Therefore, the mass 17, the pair of springs 16 mechanically connected to the mass 17, the four first movable electrodes 18, and the two pairs of second movable electrodes 20 are separated from the bottom of the cavity 14 in the +Z direction.

### [Operation of Acceleration Detection Device]

An external AC power supply is connected to the electrode pads 13a and 13b so as to apply voltages with opposite phases to the flat plate electrodes 18a and 18b of the first movable electrode 18.

When the mass 17 is not subjected to an acceleration in the X-axis direction, it is located at the zero point which is the initial position. When the mass 17 is located at the zero point, since the distance D1 between the flat plate electrode 18a of the first movable electrode 18 and the flat plate electrode 19a of the first fixed electrode 19 is equal to the distance D2 between the flat plate electrode 18b of the first movable electrode 18 and the flat plate electrode 19b of the first fixed electrode 19, a capacitance C₁ between the flat plate electrode 18a and the flat plate electrode 19a is equal to a capacitance C₂ between the flat plate electrode 18b and the flat plate electrode 19b. At this time, the potential of the first fixed electrode 19 facing the first movable electrode 18 becomes an intermediate potential V_{mid} that is between the potentials of the flat plate electrodes 18a and 18b.

When the mass 17 is subjected to an acceleration in the X-axis direction, it is displaced in the X-axis direction from the zero point which is the initial position. When the mass 17 is displaced from the zero point in the X-axis direction, since the distance D1 is different from the distance D2, the capacitance C₁ is different from the capacitance C₂. At this time, the potential of the first fixed electrode 19 facing the first movable electrode 18 becomes a potential different from the intermediate potential V_{mid}. Therefore, by detecting the potential of the first fixed electrode 19 via the electrode pads 13e, the amount of displacement of the mass 17 in the X-axis direction and the acceleration applied to the mass 17 in the X-axis direction may be calculated based on a difference between the potential of the first fixed electrode 19 and the intermediate potential V_{mid}.

An external power supply is connected to the electrode pads 13c, 13d, and 13f so as to apply voltages to the +X direction side second movable electrode 20a, the −X direction side second movable electrode 20b, and the second fixed electrode 21, respectively.

By supplying electricity between the +X direction side second movable electrode 20a, the second fixed electrode 21, and the −X direction side second movable electrode 20b, electrostatic forces F₃ and F₄ that attract each other between the +X direction side second movable electrode 20a and the second fixed electrode 21 and between the −X direction side second movable electrode 20b and the second fixed electrode 21 are generated by electrostatic induction.

It is known that an electrostatic force is inversely proportional to a square of distance. Therefore, for example, when the mass 17 is subjected to an acceleration in the +X direction and is displaced in the +X direction from the zero point which is the initial position, since a distance D3 between the +X direction side second movable electrode 20a and the second fixed electrode 21 becomes smaller, the electrostatic force F₃ between the +X direction side second movable electrode 20a and the second fixed electrode 21 becomes larger, such that the mass 17 is likely to be further displaced in the +X direction. Further, when the mass 17 is subjected to an acceleration in the −X direction and is displaced in the −X direction from the zero point which is the initial position, since a distance D4 between the −X direction side second movable electrode 20b and the second fixed electrode 21 becomes smaller, the electrostatic force F₄ between the −X direction side second movable electrode 20b and the second fixed electrode 21 becomes larger, such that the mass 17 is likely to be further displaced in the −X direction. Therefore, the electrostatic force F₃ between the +X direction side second movable electrode 20a and the second fixed electrode 21 or the electrostatic force F₄ between the −X direction side second movable electrode 20b and the second fixed electrode 21 acts in the same direction as the acceleration to assist the acceleration applied to the mass 17 and acts to oppose the restoring force of the pair of springs 16.

An overlapping area in the Y-axis direction of the movable side interdigital electrode 22a of the +X direction side second movable electrode 20a and the fixed side interdigital electrode 23a of the second fixed electrode 21 changes linearly with the displacement of the mass 17 in the X-axis direction. Similarly, an overlapping area in the Y-axis direction of the movable side interdigital electrode 22b of the −X direction side second movable electrode 20b and the fixed side interdigital electrode 23b of the second fixed electrode 21 changes linearly with the displacement of the mass 17 in the X-axis direction. It is known that a capacitance is proportional to the overlapping area of electrodes. Therefore, a capacitance C₃ between the +X direction side second movable electrode 20a and the second fixed electrode 21 and a capacitance C₄ between the −X direction side second movable electrode 20b and the second fixed electrode 21 each changes linearly with the displacement of the mass 17 in the X-axis direction.

It is known that electrostatic energy between two electrodes is proportional to a capacitance. Therefore, electrostatic energy between the +X direction side second movable electrode 20a and the second fixed electrode 21 is proportional to the capacitance C₃ and changes linearly with the displacement of the mass 17 in the X-axis direction. Similarly, electrostatic energy between the −X direction side second movable electrode 20b and the second fixed electrode 21 is proportional to the capacitance C₄ and changes linearly with the displacement of the mass 17 in the X-axis direction.

It is known that an electrostatic force (F₃, F₄) between two electrodes is calculated by differentiating electrostatic energy with a distance between the two electrodes. Therefore, the electrostatic forces F₃ and F₄ are determined according to relationships shown in Equations 1 and 2 below. In Equations 1 and 2, x is an amount of displacement of the mass 17 in the X-axis direction. Further, V_{c} is a voltage applied between the +X direction side second movable electrode 20a and the second fixed electrode 21. Further, V_{d} is a voltage applied between the −X direction side second movable electrode 20b and the second fixed electrode 21. Further, β is a value obtained by differentiating the capacitance C₃ or the capacitance C₄ with the displacement amount x.

$${F}_{3} = - \frac{d}{dx} ( - \frac{1}{2} {C}_{3} {V}_{c}^{2} ) = - \frac{β}{2} {V}_{c}^{2} \qquad [ Equation 1 ]$$

$${F}_{4} = - \frac{d}{dx} ( - \frac{1}{2} {C}_{4} {V}_{d}^{2} ) = + \frac{β}{2} {V}_{d}^{2} \qquad [ Equation 2 ]$$

A total force F_{eff} applied to the spring-mass system of the acceleration detection device 1 constituted by the pair of springs 16, the +X direction side second movable electrode 20a and the second fixed electrode 21, the −X direction side second movable electrode 20b and the second fixed electrode 21, and the mass 17 is determined by a relationship shown in Equation 3 below. In Equation 3, F_{mech} is the restoring force of the pair of springs 16.

$${F}_{eff} = {F}_{mech} + {F}_{3} + {F}_{4} = {F}_{mech} + \frac{β}{2} ( - {V}_{c}^{2} + {V}_{d}^{2} ) \qquad [ Equation 3 ]$$

When a voltage applied from the electrode pad 13c to the +X direction side second movable electrode 20a is equal to a voltage applied from the electrode pad 13d to the −X direction side second movable electrode 20b, the voltage V_{c} applied between the +X direction side second movable electrode 20a and the second fixed electrode 21 and the voltage V_{d} applied between the −X direction side second movable electrode 20b and the second fixed electrode 21 are determined according to relationships shown in Equations 4 and 5 below, respectively, with respect to the displacement amount x of the mass 17 in the X-axis direction. In Equations 4 and 5, V₀ is the voltages V_{c} and V_{d} when the mass 17 is not subjected to an acceleration in the X-axis direction. Further, γ is a coefficient determined according to shapes and sizes of the +X direction side second movable electrode 20a, the −X direction side second movable electrode 20b, and the second fixed electrode 21.

$${V}_{c} = {V}_{0} + γ x \qquad [ Equation 4 ]$$

$${V}_{d} = {V}_{0} - γ x \qquad [ Equation 5 ]$$

From relationships shown in Equations 3, 4, and 5, the relationship between the total force F_{eff} applied to the spring-mass system and the displacement amount x of the mass 17 in the X-axis direction is determined according to Equation 6 below. In Equation 6, k_{mech} is a mechanical spring constant of the pair of springs 16.

$${F}_{eff} = {F}_{mech} - 2 {βV}_{0} γ x = ( {k}_{mech} - 2 {βV}_{0} γ ) x \qquad [ Equation 6 ]$$

Therefore, the electrostatic force F₃ between the +X direction side second movable electrode 20a and the second fixed electrode 21 and the electrostatic force F₄ between the −X direction side second movable electrode 20b and the second fixed electrode 21 act as an elastic force acting in the same direction as the acceleration applied to the mass 17, that is, an elastic force opposing the restoring force of the pair of springs 16, according to the displacement amount x of the mass 17 in the X-axis direction.

A spring constant k_{eff} of the entire spring-mass system of the acceleration detection device 1 is determined according to a relationship shown in Equation 7 below. In Equation 7, k_{elec} is an electrostatic spring constant for the electrostatic force F₃ between the +X direction side second movable electrode 20a and the second fixed electrode 21 and the electrostatic force F₄ between the −X direction side second movable electrode 20b and the second fixed electrode 21.

$${k}_{eff} = {k}_{mech} + {k}_{elec} = {k}_{mech} - 2 {βV}_{0} γ \qquad [ Equation 7 ]$$

It is known that a resonance frequency f₀ of the spring-mass system is calculated according to a relationship shown in Equation 8 below. In Equation 8, m₀ is a mass value of the mass.

$${f}_{0} = \frac{1}{2 π} \sqrt{\frac{{k}_{eff}}{{m}_{0}}} \qquad [ Equation 8 ]$$

Therefore, the resonance frequency f₀ of the spring-mass system of the acceleration detection device 1 is determined according to a relationship shown in Equation 9 below.

$${f}_{0} = \frac{1}{2 π} \sqrt{\frac{{k}_{mech} + {k}_{elec}}{{m}_{0}}} = \frac{1}{2 π} \sqrt{\frac{{k}_{mech} - 2 {βV}_{0} γ}{{m}_{0}}} \qquad [ Equation 9 ]$$

A detectable range and a sensitivity of the acceleration detection device 1 are determined according to the resonance frequency f₀. As the resonance frequency f₀ becomes larger, it is more difficult for a frequency of the acceleration applied to the acceleration detection device 1 to reach the resonance frequency f₀, such that the detectable range of the acceleration detection device 1 becomes wider. As the resonance frequency f₀ becomes smaller, vibration of the mass 17 is likely to become larger, such that the sensitivity of the acceleration detection device 1 becomes higher.

### [Configuration of Acceleration Sensor]

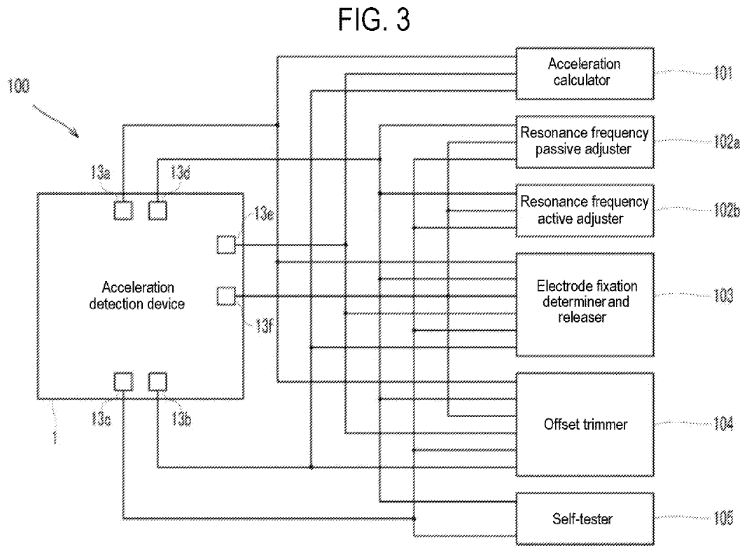

FIG. 3 is a block diagram of an acceleration sensor 100 including the acceleration detection device 1 of FIG. 1.

The acceleration sensor 100 includes an acceleration calculator 101 that is electrically connected to the electrode pads 13a, 13b, and 13e of the acceleration detection device 1. The acceleration calculator 101 calculates the acceleration in the X-axis direction, which is applied to the mass 17, according to changes in the capacitance C₁ between the flat plate electrode 18a and the flat plate electrode 19a and the capacitance C₂ between the flat plate electrode 18b and the flat plate electrode 19b.

The acceleration sensor 100 includes a resonance frequency passive adjuster 102a that is electrically connected to the electrode pads 13c, 13d, and 13f. The resonance frequency passive adjuster 102a adjusts the resonance frequency f₀ of the spring-mass system of the acceleration detection device 1 to a desired value by applying a voltage to control the electrostatic force F₃ between the +X direction side second movable electrode 20a and the second fixed electrode 21 and the electrostatic force F₄ between the −X direction side second movable electrode 20b and the second fixed electrode 21. In particular, the resonance frequency passive adjuster 102a may decrease the resonance frequency f₀ to increase the sensitivity of the acceleration detection device 1.

The acceleration sensor 100 includes a resonance frequency active adjuster 102b that is electrically connected to the electrode pads 13c, 13d, and 13f. The resonance frequency active adjuster 102b adjusts the resonance frequency f₀ of the spring-mass system of the acceleration detection device 1 to a desired value by applying a voltage to control the electrostatic force F₃ between the +X direction side second movable electrode 20a and the second fixed electrode 21 and the electrostatic force F₄ between the −X direction side second movable electrode 20b and the second fixed electrode 21. In particular, the resonance frequency active adjuster 102b may increase the resonance frequency f₀ to widen the detectable range of the acceleration detection device 1.

The acceleration sensor 100 includes an electrode fixation determiner and releaser 103 that is electrically connected to the electrode pads 13a, 13b, 13c, 13d, 13e, and 13f. The electrode fixation determiner and releaser 103 detects the position of the mass 17 based on the potential of the second fixed electrode 21 when a voltage is applied to the two pairs of second movable electrodes 20, and determines whether or not the first movable electrode 18 and the first fixed electrode 19 are fixed. After it is determined that the first movable electrode 18 and the first fixed electrode 19 are fixed, the electrode fixation determiner and releaser 103 displaces the mass 17 in the X-axis direction to release the fixation between the first movable electrode 18 and the first fixed electrode 19 by applying a voltage to control an electrostatic force F₁ between the flat plate electrode 18a of the first movable electrode 18 and the flat plate electrode 19a of the first fixed electrode 19, an electrostatic force F₂ between the flat plate electrode 18b of the first movable electrode 18 and the flat plate electrode 19b of the first fixed electrode 19, the electrostatic force F₃ between the +X direction side second movable electrode 20a and the second fixed electrode 21, and the electrostatic force F₄ between the −X direction side second movable electrode 20b and the second fixed electrode 21.

The acceleration sensor 100 includes an offset trimmer 104 that is electrically connected to the electrode pads 13a, 13b, 13c, 13d, 13e, and 13f. When the mass 17 is not subjected to an acceleration in the X-axis direction, the offset trimmer 104 displaces the mass 17 in the X-axis direction to execute an offset to correct the zero point of the mass 17 by applying a voltage to control the electrostatic force F₃ between the +X direction side second movable electrode 20a and the second fixed electrode 21 and the electrostatic force F₄ between the −X direction side second movable electrode 20b and the second fixed electrode 21.

The acceleration sensor 100 includes a self-tester 105 that is electrically connected to the electrode pads 13c and 13d. When performing a self-test to diagnose whether or not an acceleration may be calculated, the self-tester 105 displaces the mass 17 in the X-axis direction by applying a voltage to control the electrostatic force F₃ between the +X direction side second movable electrode 20a and the second fixed electrode 21 and the electrostatic force F₄ between the −X direction side second movable electrode 20b and the second fixed electrode 21.

In the present embodiment, the acceleration calculator 101, the resonance frequency passive adjuster 102a, the resonance frequency active adjuster 102b, the electrode fixation determiner and releaser 103, the offset trimmer 104, and the self-tester 105 are, together with the acceleration detection device 1, realized by an ASIC (Application Specific Integrated Circuit) installed in the acceleration sensor 100, and include respective memories in which programs which execute respective functions are stored.

In the present embodiment, the acceleration sensor 100 includes the resonance frequency passive adjuster 102a and the resonance frequency active adjuster 102b, but it may include only one of them, or may include a single resonance frequency adjuster that has the respective functions collectively.

In the present embodiment, the acceleration sensor 100 includes the electrode fixation determiner and releaser 103, but it may include an electrode fixation determiner configured to determine whether or not the first movable electrode 18 and the first fixed electrode 19 are fixed, and an electrode fixation releaser configured to release the fixation between the first movable electrode 18 and the first fixed electrode 19.

### [Acceleration Calculator]

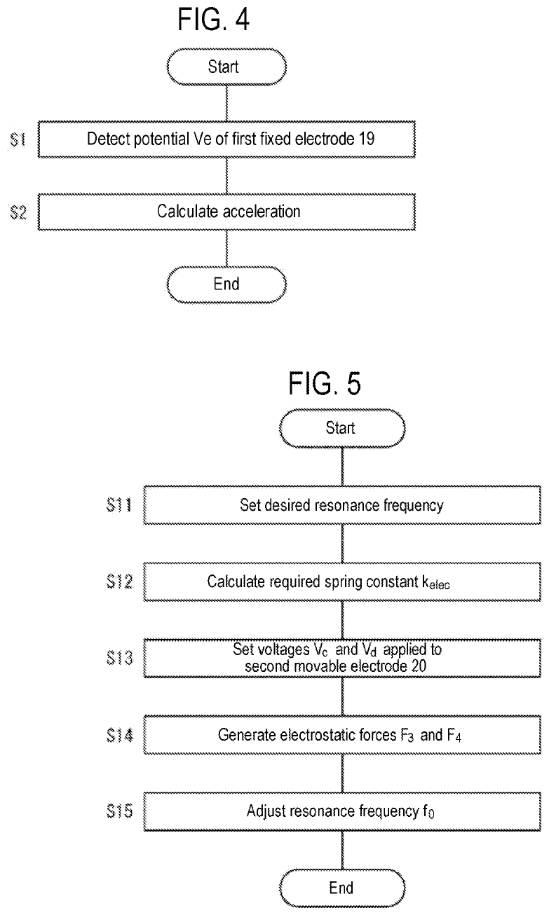

FIG. 4 is a flowchart of acceleration calculation performed by the acceleration calculator 101 of FIG. 3, particularly showing a control process executed by the acceleration calculator 101. A program that calculates an acceleration according to the depicted flowchart is stored in the memory of the acceleration calculator 101.

In step S1, the acceleration calculator 101 detects a potential V_{c} of the first fixed electrode 19 via the electrode pad 13e.

As described above, the external AC power supply is connected to the electrode pads 13a and 13b so as to apply voltages with opposite phases to the flat plate electrodes 18a and 18b of the first movable electrode 18. When the mass 17 is not subjected to an acceleration in the X-axis direction, the potential Vₑ of the first fixed electrode 19 becomes the intermediate potential V_{mid} which is between the potentials of the flat plate electrodes 18a and 18b. When the mass 17 is subjected to the acceleration in the X-axis direction, the potential Vₑ of the first fixed electrode 19 becomes a potential different from the intermediate potential V_{mid}. The acceleration calculator 101 detects the potential Vₑ of the first fixed electrode 19, which changes according to the acceleration in the X-axis direction applied to the mass 17.

In the present embodiment, a voltage of 1.0 V is applied to the flat plate electrode 18a via the electrode pad 13a. Further, a voltage of 4.0 V is applied to the flat plate electrode 18b via the electrode pad 13b. Therefore, the intermediate potential V_{mid} is 2.5 V. The voltages applied to the flat plate electrode 18a and the flat plate electrode 18b and the intermediate potential V_{mid} are not limited to the above-mentioned values, and various values may be set.

In step S2, the acceleration calculator 101 calculates the acceleration in the X-axis direction applied to the mass 17 based on the detected potential Vₑ of the first fixed electrode 19. In particular, the acceleration calculator 101 calculates the displacement amount of the mass 17 in the X-axis direction and the acceleration applied to the mass 17 in the X-axis direction based on a difference between the potential of the first fixed electrode 19 and the intermediate potential V_{mid}.

In the present embodiment, the acceleration calculator 101 includes an amplification circuit configured to amplify the difference between the potential of the first fixed electrode 19 and the intermediate potential V_{mid}. The acceleration calculator 101 may amplify and calculate the acceleration in the X-axis direction applied to the mass 17 by amplifying the difference between the potential of the first fixed electrode 19 and the intermediate potential V_{mid}.

### [Resonance Frequency Passive Adjuster]

FIG. 5 is a flowchart of resonance frequency adjustment performed by the resonance frequency passive adjuster 102a of FIG. 3, particularly showing a control process executed by the resonance frequency passive adjuster 102a. A program that adjusts a resonance frequency according to the depicted flowchart is stored in the memory of the resonance frequency passive adjuster 102a.

In step S11, the resonance frequency passive adjuster 102a sets a desired resonance frequency from the outside according to its use. In particular, the desired resonance frequency is set based on a request to increase the sensitivity of the acceleration sensor 100. The desired resonance frequency may be set by a user or automatically by an external control part.

In step S12, the resonance frequency passive adjuster 102a calculates a required electrostatic spring constant k_{elec} based on the set desired resonance frequency. This electrostatic spring constant k_{elec} is calculated based on the relationship shown in Equation 9.

In step S13, based on the calculated electrostatic spring constant k_{elec}, the resonance frequency passive adjuster 102a sets voltages applied to the second movable electrode 20, particularly the voltage V_{c} applied between the +X direction side second movable electrode 20a and the second fixed electrode 21 and the voltage V_{d} applied between the −X direction side second movable electrode 20b and the second fixed electrode 21. These voltages V_{c} and V_{d} are a voltage V₀ calculated based on the relationship shown in Equation 7.

In the present embodiment, the voltage V₀ is set to 1.5 V. In particular, a voltage of 4.5 V is applied to the +X direction side second movable electrode 20a via the electrode pad 13c. A voltage of 3.0 V is applied to the second fixed electrode 21 via the electrode pad 13f. A voltage of 1.5 V is applied to the −X direction side second movable electrode 20b via the electrode pad 13d. The voltages applied to the +X direction side second movable electrode 20a, the −X direction side second movable electrode 20b, and the second fixed electrode 21 are not limited to the above-mentioned values, and various values may be set.

In step S14, as the voltages V_{c} and V_{d} are applied between the +X direction side second movable electrode 20a and the second fixed electrode 21 and between the −X direction side second movable electrode 20b and the second fixed electrode 21, the electrostatic forces F₃ and F₄ are respectively generated. Since the voltage V_{c} between the +X direction side second movable electrode 20a and the second fixed electrode 21 is equal to the voltage V_{d} between the −X direction side second movable electrode 20b and the second fixed electrode 21, the electrostatic forces F₃ and F₄ act so as to have equal magnitude and oppose each other according to the relationships shown in Equations 1 and 2.

As described above, the resonance frequency f₀ of the spring-mass system of the acceleration detection device 1 to which the electrostatic forces F₃ and F₄ are applied is adjusted (step S15). When the mass 17 is not subjected to the acceleration in the X-axis direction, since the electrostatic forces F₃ and F₄ balance each other, the mass 17 continues to be located at the zero point. When the mass 17 is subjected to the acceleration in the X-axis direction, one of the electrostatic forces F₃ and F₄ acting in the same direction as the acceleration applied to the mass 17 becomes larger, and the other of the electrostatic forces F₃ and F₄ acting in the opposite direction to the acceleration applied to the mass 17 becomes smaller. For example, when the mass 17 is subjected to the acceleration in the +X direction, since the mass 17 moves in the +X direction side to increase the distance D3 between the +X direction side second movable electrode 20a and the second fixed electrode 21, the electrostatic force F₃ becomes smaller. On the other hand, since the distance D4 between the −X direction side second movable electrode 20b and the second fixed electrode 21 decreases, the electrostatic force F₄ becomes larger.

Therefore, the electrostatic forces F₃ and F₄ act as a whole to assist the acceleration applied to the mass 17 and oppose the restoring force F_{mech} of the pair of springs 16. As the electrostatic forces F₃ and F₄ oppose the restoring force F_{mech} of the pair of springs 16, the spring-mass system of the acceleration detection device 1 is likely to vibrate, and the resonance frequency f₀ becomes small. As the resonance frequency f₀ becomes smaller, the spring-mass system is likely to vibrate even in a case where the acceleration applied to the mass 17 is at a low frequency, such that the sensitivity of the acceleration detection device 1 may be increased.

### [Resonance Frequency Active Adjuster]

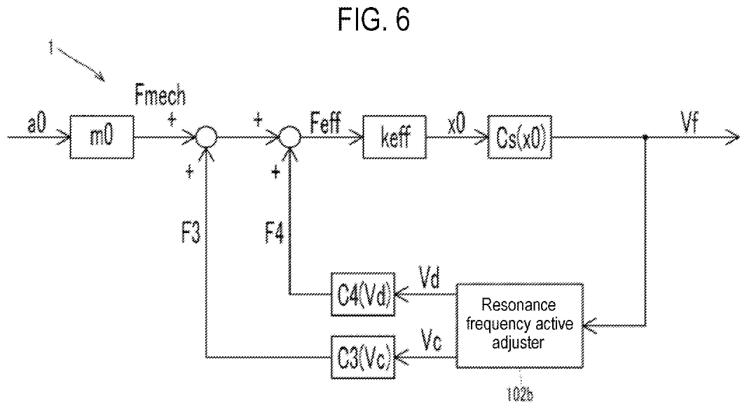

FIG. 6 is a block diagram of the acceleration detection device 1 and the resonance frequency active adjuster 102b of FIG. 3. As shown, the acceleration detection device 1 and the resonance frequency active adjuster 102b constitute a feedback system.

When an acceleration a₀ is applied to the mass 17, the mass 17 moves in the X-axis direction with a displacement amount x₀ according to the spring constant k_{eff} of the entire spring-mass system of the acceleration detection device 1.

When the mass 17 moves with the displacement amount x₀, the capacitance C₃ between the +X direction side second movable electrode 20a and the second fixed electrode 21 and the capacitance C₄ between the −X direction side second movable electrode 20b and the second fixed electrode 21 each vary linearly with the displacement amount x₀ of the mass 17 in the X-axis direction. Therefore, the potential V_{f} of the second fixed electrode 21 changes according to the displacement amount x₀ of the mass 17.

Depending on the detected potential V_{f} of the second fixed electrode 21, the resonance frequency active adjuster 102b sets the voltage V_{c} applied between the +X direction side second movable electrode 20a and the second fixed electrode 21 and the voltage V_{d} applied between the −X direction side second movable electrode 20b and the second fixed electrode 21. In particular, the resonance frequency active adjuster 102b sets the voltages V_{c} and V_{d} such that the electrostatic forces F₃ and F₄ assist the restoring force F_{mech} of the pair of springs 16 in opposition to the acceleration a₀ applied to the mass 17.

As the voltages V_{c} and V_{d} are applied between the +X direction side second movable electrode 20a and the second fixed electrode 21 and between the −X direction side second movable electrode 20b and the second fixed electrode 21, the electrostatic forces F₃ and F₄ are respectively generated. In particular, one of the electrostatic forces F₃ and F₄ acting in the same direction as the acceleration applied to the mass 17 becomes smaller, and the other of the electrostatic forces F₃ and F₄ acting in the opposite direction to the acceleration applied to the mass 17 becomes larger. For example, when mass 17 is subjected to the acceleration in the +X direction, the electrostatic force F₄ acting in the same direction as the acceleration in the +X direction becomes smaller. On the other hand, the electrostatic force F₃ acting in the direction opposite to the acceleration in the +X direction becomes larger.

The total force F_{eff}, which is a sum of the electrostatic forces F₃ and F₄ and a force due to the acceleration a₀, acts on the entire spring-mass system of the acceleration detection device 1. The electrostatic forces F₃ and F₄ act as a whole to oppose the acceleration applied to the mass 17 to assist the restoring force F_{mech}. Therefore, the spring constant k_{eff} of the entire spring-mass system becomes larger than the mechanical spring constant k_{mech} of the pair of springs 16.

Since the spring constant k_{eff} of the entire spring-mass system becomes larger than the mechanical spring constant k_{mech} of the pair of springs 16, the resonance frequency f₀ of the entire spring-mass system becomes larger according to the relationship shown in Equation 8.

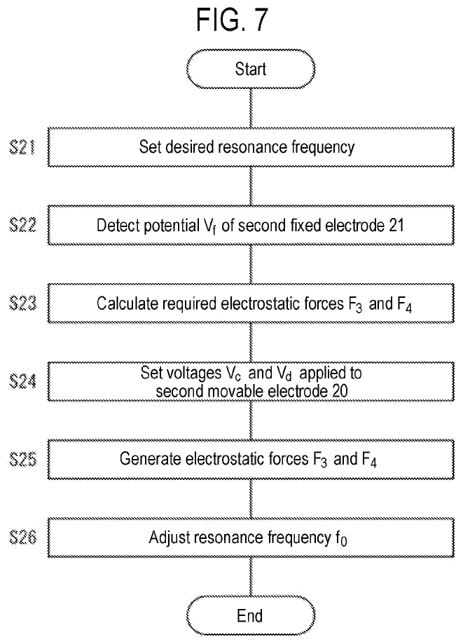

FIG. 7 is a flowchart of resonance frequency adjustment performed by the resonance frequency active adjuster 102b of FIG. 6, particularly showing a control process executed by the resonance frequency active adjuster 102b. A program that adjusts a resonance frequency according to the illustrated flowchart is stored in the memory of the resonance frequency active adjuster 102b.

In step S21, the resonance frequency active adjuster 102b sets a desired resonance frequency from the outside according to its use. In particular, the desired resonance frequency is set based on a request to widen the detectable range of the acceleration sensor 100. The desired resonance frequency may be set by a user or automatically by an external controller.

In step S22, the resonance frequency active adjuster 102b detects the potential V_{f} of the second fixed electrode 21 via the electrode pad 13f.

An external power supply is connected to the electrode pads 13c and 13d for the +X direction side second movable electrode 20a and the −X direction side second movable electrode 20b. When the mass 17 is not subjected to the acceleration a₀ in the X-axis direction, the potential V_{f} of the second fixed electrode 21 becomes an intermediate potential that is between the potentials of the +X direction side second movable electrode 20a and the −X direction side second movable electrode 20b. When the mass 17 is subjected to the acceleration a₀ in the X-axis direction, the potential V_{f} of the second fixed electrode 21 becomes a potential different from the intermediate potential. Therefore, the resonance frequency active adjuster 102b detects the potential V_{f} of the second fixed electrode 21, which changes according to the acceleration a₀ in the X-axis direction applied to the mass 17.

In step S23, the resonance frequency active adjuster 102b calculates the required electrostatic forces F₃ and F₄ based on the set desired resonance frequency. These electrostatic forces F₃ and F₄ are calculated based on the relationships shown in Equations 6 and 9. In particular, the resonance frequency active adjuster 102b calculates the electrostatic forces F₃ and F₄ such that one of the electrostatic forces F₃ and F₄ acting in the same direction as the acceleration applied to the mass 17 becomes smaller and the other of the electrostatic forces F₃ and F₄ acting in the opposite direction to the acceleration applied to the mass 17 becomes larger.

In step S24, based on the calculated electrostatic forces F₃ and F₄, the resonance frequency active adjuster 102b sets voltages applied to the second movable electrode 20, particularly the voltage V_{c} applied between the +X direction side second movable electrode 20a and the second fixed electrode 21 and the voltage V_{d} applied between the −X direction side second movable electrode 20b and the second fixed electrode 21.

In step S25, as the voltages V_{c} and V_{d} are applied between the +X direction side second movable electrode 20a and the second fixed electrode 21 and between the −X direction side second movable electrode 20b and the second fixed electrode 21, the electrostatic forces F₃ and F₄ are respectively generated. Since one of the electrostatic forces F₃ and F₄ acting in the same direction as the acceleration applied to the mass 17 becomes smaller and the other of the electrostatic force F₃ and F₄ acting in the opposite direction to the acceleration applied to the mass 17 becomes larger, the electrostatic forces F₃ and F₄ act as a whole to assist the restoring force F_{mech} of the pair of springs 16 in opposition to the acceleration a₀ applied to the mass 17. Since the electrostatic forces F₃ and F₄ act to assist the restoring force F_{mech}, the spring constant k_{eff} of the entire spring-mass system becomes larger than the mechanical spring constant k_{mech} of the pair of springs 16.

As described above, the resonance frequency f₀ of the spring-mass system of the acceleration detection device 1 to which the electrostatic forces F₃ and F₄ are applied is adjusted (step S26). The electrostatic forces F₃ and F₄ act to assist the restoring force F_{mech} of the pair of springs 16 in opposition to the acceleration a₀ applied to the mass 17. Therefore, the spring-mass system of the acceleration detection device 1 becomes difficult to vibrate, and the resonance frequency f₀ increases. By increasing the resonance frequency f₀, it becomes difficult for a frequency of the acceleration a₀ to reach the resonance frequency f₀, such that the detectable range of the acceleration detection device 1 may be widened.

### [Electrode Fixation Determiner and Releaser]

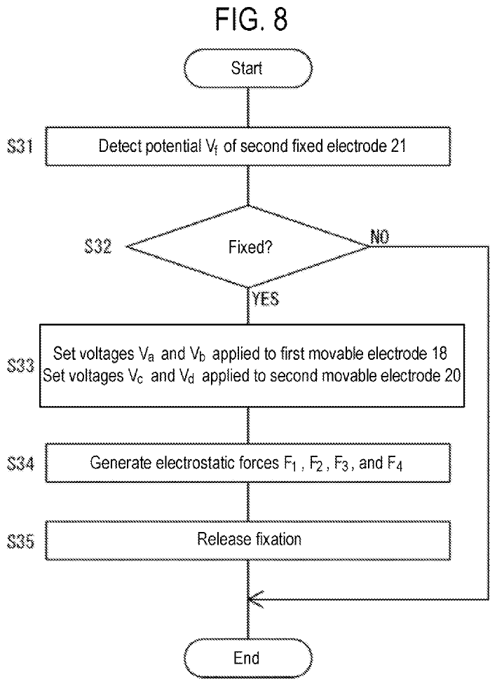

FIG. 8 is a flowchart for determining and releasing electrode fixation performed by the electrode fixation determiner and releaser 103 in FIG. 3, particularly showing a control process executed by the electrode fixation determiner and releaser 103. A program that determines and releases the electrode fixation according to the depicted flowchart is stored in the memory of the electrode fixation determiner and releaser 103.

In step S31, the electrode fixation determiner and releaser 103 detects the potential V_{f} of the second fixed electrode 21 via the electrode pad 13f.

An external power supply is connected to the electrode pads 13c and 13d for the +X direction side second movable electrode 20a and the −X direction side second movable electrode 20b. When the mass 17 is not displaced in the X-axis direction, the potential V_{f} of the second fixed electrode 21 becomes an intermediate potential that is between the potentials of the +X direction side second movable electrode 20a and the −X direction side second movable electrode 20b. When the mass 17 is displaced in the X-axis direction, the potential V_{f} of the second fixed electrode 21 becomes a potential different from the intermediate potential. Therefore, the electrode fixation determiner and releaser 103 detects the potential V_{f} of the second fixed electrode 21, which changes according to the displacement of the mass 17 in the X-axis direction.

In step S32, the electrode fixation determiner and releaser 103 calculates the displacement amount of the mass 17 in the X-axis direction based on the potential V_{f} of the second fixed electrode 21 and determines whether or not the first movable electrode 18 and the first fixed electrode 19 are fixed. In particular, when the mass 17 is not displaced in the X-axis direction by a distance equal to the distances D1 and D2 (NO in step S32), the control process ends. On the other hand, when the mass 17 is displaced in the X-axis direction by a distance equal to the distances D1 and D2 (YES in step S32), it is determined that the first movable electrode 18 and the first fixed electrode 19 are fixed, and the control process proceeds to the next step S33.

In step S33, in order to release the fixation between the first movable electrode 18 and the first fixed electrode 19, the electrode fixation determiner and releaser 103 sets voltages to applied to the first movable electrode 18, particularly a voltage V_{d} applied between the flat plate electrode 18a of the first movable electrode 18 and the flat plate electrode 19a of the first fixed electrode 19 and a voltage V_{b} applied between the flat plate electrode 18b of the first movable electrode 18 and the flat plate electrode 19b of the first fixed electrode 19, and the voltages applied to the second movable electrode 20, particularly the voltage V_{c} applied between the +X direction side second movable electrode 20a and the second fixed electrode 21 and the voltage V_{d} applied between the −X direction side second movable electrode 20b and the second fixed electrode 21.

In the present embodiment, the voltage V_{d} applied between the flat plate electrode 18a of the first movable electrode 18 and the flat plate electrode 19a of the first fixed electrode 19 is set to 0 V. The voltage V_{b} applied between the flat plate electrode 18b of the first movable electrode 18 and the flat plate electrode 19b of the first fixed electrode 19 is set to 5.0 V. The voltage V_{c} applied between the +X direction side second movable electrode 20a and the second fixed electrode 21 is set to 15.0 V. The voltage V_{d} applied between the −X direction side second movable electrode 20b and the second fixed electrode 21 is set to 0 V. In particular, a voltage of 15.0 V is applied to the +X direction side second movable electrode 20a via the electrode pad 13c. A voltage of 5.0 V is applied to the flat plate electrode 18b of the first movable electrode 18 via the electrode pad 13b. The voltages applied to the flat plate electrodes 18a and 18b of the first movable electrode 18, the first fixed electrode 19, the +X direction side second movable electrode 20a, the −X direction side second movable electrode 20b, and the second fixed electrode 21 are not limited to the above-mentioned values, and various values may be set.

In step S34, as the voltages Vₐ, V_{b}, V_{c}, and V_{d} are applied between the flat plate electrode 18a of the first movable electrode 18 and the flat plate electrode 19a of the first fixed electrode 19, between the flat plate electrode 18b of the first movable electrode 18 and the flat plate electrode 19b of the first fixed electrode 19, between the +X direction side second movable electrode 20a and the second fixed electrode 21, and between the −X direction side second movable electrode 20b and the second fixed electrode 21, the electrostatic forces F₁, F₂, F₃, and F₄ are respectively generated.

In the present embodiment, since the voltages V_{d} and V_{c} are applied only between the flat plate electrode 18a of the first movable electrode 18 and the flat plate electrode 19a of the first fixed electrode 19 and between the +X direction side second movable electrode 20a and the second fixed electrode 21, only the electrostatic forces F₁ and F₃ are generated. Due to the electrostatic forces F₁ and F₃, the mass 17 is displaced in the X-axis direction so as to release the fixation between the first movable electrode 18 and the first fixed electrode 19.

As described above, the fixation between the first movable electrode 18 and the first fixed electrode 19 in the spring-mass system of the acceleration detection device 1 to which the electrostatic forces F₁, F₂, F₃, and F₄ are applied is released (step S35).

In the present embodiment, in step S32, the electrode fixation determiner and releaser 103 determines whether or not the mass 17 is displaced in the X-axis direction by a distance equal to the distances D1 and D2. However, the electrode fixation determiner and releaser 103 may set a threshold value based on a stroke amount of the first movable electrode 18 with respect to the first fixed electrode 19 with which the acceleration calculator 101 may stably calculate an acceleration, to determine the fixation between the first movable electrode 18 and the first fixed electrode 19.

### [Offset Trimmer]

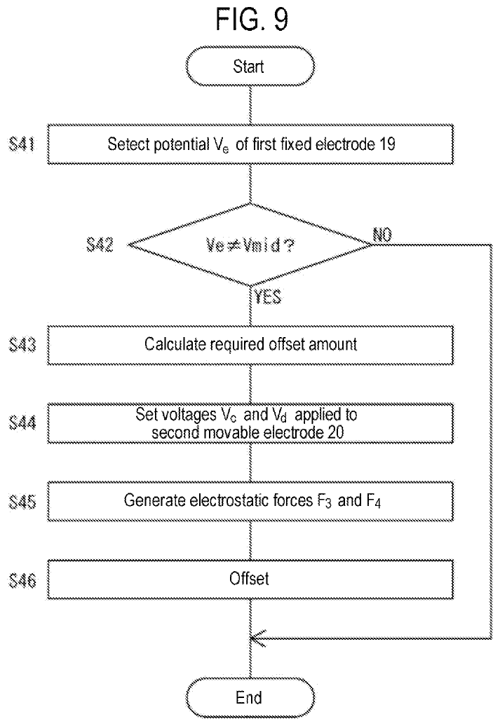

FIG. 9 is a flowchart of offset trim performed by the offset trimmer 104 in FIG. 3, particularly showing a control process executed by the offset trimmer 104. A program that performs an offset to correct the zero point of the mass 17 according to the depicted flowchart is stored in the memory of the offset trimmer 104.

In step S41, for example, when performing calibration at the time of product shipment, the offset trimmer 104 detects the potential V_{c} of the first fixed electrode 19 via the electrode pad 13e in a state where an acceleration in the X-axis direction is not applied to the mass 17.

In step S42, the offset trimmer 104 determines whether or not the potential V_{c} of the first fixed electrode 19 matches the intermediate potential V_{mid} that is between the potentials of the flat plate electrodes 18a and 18b. In particular, when the potential V_{c} matches the intermediate potential V_{mid} (NO in step S42), the control process ends. On the other hand, when the potential V_{c} does not match the intermediate potential V_{mid} (YES in step S42), it is determined that the zero point of the mass 17 is shifted, and the control process proceeds to the next step S43.

In step S43, the offset trimmer 104 calculates an offset amount required to correct the zero point of the mass 17 based on a difference between the potential V_{c} of the first fixed electrode 19 and the intermediate potential V_{mid} when the acceleration in the X-axis direction is not applied to the mass 17.

In step S44, based on the offset amount required to correct the zero point of the mass 17, the offset trimmer 104 sets the voltages applied to the second movable electrode 20, particularly the voltage V_{c} applied between the +X direction side second movable electrode 20a and the second fixed electrode 21 and the voltage V_{d} applied between the −X direction side second movable electrode 20b and the second fixed electrode 21.

In the present embodiment, the voltage V_{c} applied between the +X direction side second movable electrode 20a and the second fixed electrode 21 is set to 1.55 V. Further, the voltage V_{d} applied between the −X direction side second movable electrode 20b and the second fixed electrode 21 is set to 1.5 V. In particular, a voltage of 4.55 V is applied to the +X direction side second movable electrode 20a via the electrode pad 13c. A voltage of 3.0 V is applied to the second fixed electrode 21 via the electrode pad 13f. A voltage of 1.5 V is applied to the −X direction side second movable electrode 20b via the electrode pad 13d. The voltages applied to the +X direction side second movable electrode 20a, the −X direction side second movable electrode 20b, and the second fixed electrode 21 are not limited to the above-mentioned values, and various values may be set.

In step S45, as the voltages V_{c} and V_{d} are applied between the +X direction side second movable electrode 20a and the second fixed electrode 21 and between the −X direction side second movable electrode 20b and the second fixed electrode 21, the electrostatic forces F₃ and F₄ are respectively generated. As the voltage V_{c} becomes larger than the voltage Vₐ, since the electrostatic force F₃ becomes larger than the electrostatic force F₄, the mass 17 is displaced in the X-axis direction so as to correct the zero point.

As described above, the mass 17 is displaced in the X-axis direction to be offset to correct the zero point (step S46).

### [Self-Tester]

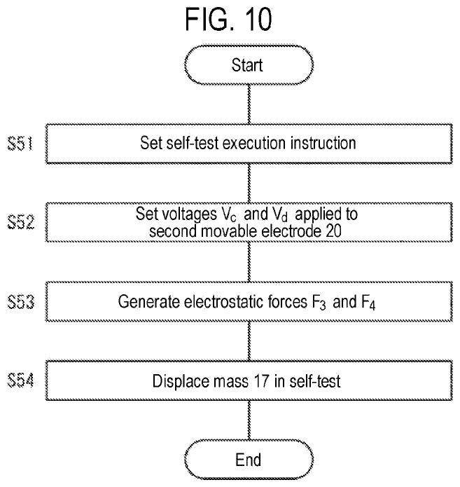

FIG. 10 is a flowchart of self-test performed by the self-tester 105 in FIG. 3, particularly showing a control process executed by the self-tester 105. A program that displaces the mass 17 in the self-test according to the depicted flowchart is stored in the memory of the self-tester 105.

In step S51, the self-tester 105 receives a self-test execution instruction from the outside. The self-test execution instruction may be given by the user or automatically by an external controller.

In step S52, in order to displace the mass 17 in the self-test, the self-tester 105 sets the voltages applied to the second movable electrode 20, particularly the voltage V_{c} applied between the +X direction side second movable electrode 20a and the second fixed electrode 21 and the voltage V_{d} applied between the −X direction side second movable electrode 20b and the second fixed electrode 21.

In the present embodiment, the voltage V_{c} applied between the +X direction side second movable electrode 20a and the second fixed electrode 21 is set to 1.0 V. Further, the voltage Vₐ applied between the −X direction side second movable electrode 20b and the second fixed electrode 21 is set to 2.0 V. In particular, a voltage of 6.0 V is applied to the +X direction side second movable electrode 20a via the electrode pad 13c. A voltage of 5.0 V is applied to the second fixed electrode 21 via the electrode pad 13f. A voltage of 3.0 V is applied to the −X direction side second movable electrode 20b via the electrode pad 13d. The voltages applied to the +X direction side second movable electrode 20a, the −X direction side second movable electrode 20b, and the second fixed electrode 21 are not limited to the above-mentioned values, and various values may be set.

In step S53, as the voltages V_{c} and V_{d} are applied between the +X direction side second movable electrode 20a and the second fixed electrode 21 and between the −X direction side second movable electrode 20b and the second fixed electrode 21, the electrostatic forces F₃ and F₄ are respectively output. As the voltage V_{d} becomes larger than the voltage V_{c}, since the electrostatic force F₄ becomes larger than the electrostatic force F₃, the mass 17 is displaced in the X-axis direction.

As described above, the mass 17 is displaced in the X-axis direction in the self-test (step S54). In a case where the acceleration calculator 101 may calculate a displacement amount of the mass 17 in the X-axis direction and an acceleration in the X-axis direction applied to the mass 17 with respect to the displacement of the mass 17 in the X-axis direction by the self-tester 105, it is known that the acceleration sensor 100 can calculate an acceleration.

In the present embodiment, in step S54, the acceleration sensor 100 determines that the acceleration can be calculated in a case where the acceleration calculator 101 can calculate the displacement amount of the mass 17 in the X-axis direction and the acceleration in the X-axis direction applied to the mass 17 with respect to the displacement of the mass 17 in the X-axis direction by the self-tester 105. However, in a case where the calculated displacement amount and acceleration match the theoretical values based on the voltages V_{c} and V_{d} set by the self-tester 105, it may be determined that the acceleration can be calculated.

### [Operation and Effects]

According to the acceleration detection device 1 and the acceleration sensor 100 according to the above-described embodiment, the following effects are exhibited.

The acceleration detection device 1 of the present disclosure may adjust the resonance frequency f₀ of the spring-mass system constituted by the pair of springs 16 and the mass 17 and displace the mass 17 in the X-axis direction by controlling the electrostatic forces F₃ and F₄ generated between the second fixed electrode 21 and the +X direction side second movable electrode 20a and between the second fixed electrode 21 and the −X direction side second movable electrode 20b, respectively. By adjusting the resonance frequency f₀, the detectable range and sensitivity of the acceleration detection device 1 may be varied. Further, the position of the mass may be detected based on the potential V_{f} of the second fixed electrode 21 when a voltage is applied to the +X direction side second movable electrode 20a and the −X direction side second movable electrode 20b.

As the +X direction side second movable electrode 20a and the −X direction side second movable electrode 20b, and the second fixed electrode 21 include the movable side interdigital electrodes 22a and 22b facing each other in the Y-axis direction with an interval therebetween and the fixed side interdigital electrodes 23a and 23b, respectively, when the mass 17 is displaced in the X-axis direction, since the capacitances C₃ and C₄ between the +X direction side second movable electrode 20a and the second fixed electrode 21 and between the −X direction side second movable electrode 20b and the second fixed electrode 21 change linearly, it is easy to adjust the resonance frequency f₀ and also the position of the mass 17.

The acceleration detection device 1 includes the isolation joint 24 at a location mechanically connected to each electrode, thereby electrically insulating each electrode to make it easy to prevent electrical interference between the respective electrodes.

Further, the acceleration sensor 100 of the present disclosure may adjust the detectable range and sensitivity of an acceleration, which may be detected by using the acceleration detection device 1, by the resonance frequency passive adjuster 102a and the resonance frequency active adjuster 102b. After the detectable range and sensitivity of the acceleration are adjusted by the resonance frequency passive adjuster 102a and the resonance frequency active adjuster 102b, the acceleration may be detected with the desired detectable range and sensitivity by the acceleration calculator 101.

After it is determined by the electrode fixation determiner and releaser 103 that the first movable electrode 18 and the first fixed electrode 19 are fixed, the fixation between the first movable electrode 18 and the first fixed electrode 19 may be released by the electrode fixation determiner and releaser 103.

When the zero point of the mass 17 in the X-axis direction is shifted, the zero point may be corrected by the offset trimmer 104.

When the self-test to diagnose whether or not an acceleration can be calculated is performed by the self-tester 105, the self-tester 105 may displace the mass 17 in the X-axis direction and diagnose whether or not an acceleration can be calculated according to a change in capacitance between the first movable electrode 18 and the first fixed electrode 19.

### Other Embodiments

Note that the present disclosure is not limited to the configuration of the above-described embodiment, and various changes are possible.

In the above-described embodiment, the acceleration detection device 1 includes the pair of springs 16, the four first movable electrodes 18, and the four first fixed electrodes 19, but it may include a single spring, a single first movable electrode, and a single first fixed electrode.

In the above-described embodiment, the second movable electrode 20 includes the movable side interdigital electrodes 22a and 22b, and the second fixed electrode 21 includes the fixed side interdigital electrodes 23a and 23b, but each of the second movable electrode and the second fixed electrode may be a flat plate electrode.

A first aspect of the present disclosure provides an acceleration detection device including:
a substrate including a cavity;
an anchor that is mechanically connected to the substrate inside the cavity;
a spring that is mechanically connected to the anchor and is expandable and contractible in a first direction;
a mass that is mechanically connected to the spring and is displaceable in the first direction by being separated from the substrate;
a first movable electrode that is mechanically connected to and electrically insulated from the mass, extends from the mass in a second direction perpendicular to the first direction, and is displaceable in the first direction together with the mass by being separated from the substrate;
a first fixed electrode that is mechanically connected to and electrically insulated from the substrate and faces the first movable electrode at an interval in the first direction;
a pair of second movable electrodes that face each other at an interval in the first direction by being mechanically connected to and electrically insulated from the mass, extend from the mass in the second direction, and are displaceable in the first direction together with the mass by being separated from the substrate; and
a second fixed electrode that is mechanically connected to and electrically insulated from the substrate so as to be interposed between the pair of second movable electrodes, the second fixed electrode being configured to generate an electrostatic force between the pair of second movable electrodes and the second fixed electrode when a voltage is applied to each of the pair of second movable electrodes and the second fixed electrode.

A second aspect of the present disclosure provides the acceleration detection device of the first aspect, wherein the pair of second movable electrodes and the second fixed electrode each include a movable side interdigital electrode and a fixed side interdigital electrode extending in the first direction and facing each other in the second direction at an interval.

A third aspect of the present disclosure provides the acceleration detection device of the first or second aspect, further including: an isolation joint that mechanically connects the anchor and the spring and electrically insulates the anchor from the spring, mechanically connects the spring and the mass and electrically insulates the spring from the mass, mechanically connects the mass and the first movable electrode and electrically insulates the mass from the first movable electrode, mechanically connects the substrate and the first fixed electrode and electrically insulates the substrate from the first fixed electrode, mechanically connects the mass and the pair of second movable electrodes and electrically insulates the mass from the pair of second movable electrodes, and mechanically connects the substrate and the second fixed electrode and electrically insulates the substrate from the second fixed electrode.

A fourth aspect of the present disclosure provides an acceleration sensor including:
the acceleration detection device of the first aspect;
a resonance frequency adjuster configured to adjust a resonance frequency of a spring-mass system constituted by the spring and the mass by applying a voltage to control the electrostatic force between the pair of second movable electrodes and the second fixed electrode; and
an acceleration calculator configured to calculate an acceleration according to a change in capacitance between the first movable electrode and the first fixed electrode.

A fifth aspect of the present disclosure provides the acceleration sensor of the fourth aspect, further including:
an electrode fixation determiner configured to detect a position of the mass based on a potential of the second fixed electrode when a voltage is applied to the pair of second movable electrodes and determine whether or not the first movable electrode and the first fixed electrode are fixed; and
an electrode fixation releaser configured to, after the electrode fixation determiner determines that the first movable electrode and the first fixed electrode are fixed, release the fixation between the first movable electrode and the first fixed electrode by applying a voltage to control the electrostatic force between the pair of second movable electrodes and the second fixed electrode and displacing the mass in the first direction.

A sixth aspect of the present disclosure provides the acceleration sensor of the fourth or fifth aspect, further including: an offset trimmer configured to correct a zero point of the mass in the first direction when an acceleration is not applied to the mass, by applying a voltage to control the electrostatic force between the pair of second movable electrodes and the second fixed electrode and displacing the mass in the first direction.

A seventh aspect of the present disclosure provides the acceleration sensor of the fourth or fifth aspect, further including: a self-tester configured to, when performing a self-test to diagnose whether or not an acceleration is capable of being calculated, apply a voltage to control the electrostatic force between the pair of second movable electrodes and the second fixed electrode and displace the mass in the first direction.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An acceleration detection device comprising:
a substrate including a cavity;
an anchor that is mechanically connected to the substrate inside the cavity;
a spring that is mechanically connected to the anchor and is expandable and contractible in a first direction;
a mass that is mechanically connected to the spring and is displaceable in the first direction by being separated from the substrate;
a first movable electrode that is mechanically connected to and electrically insulated from the mass, extends from the mass in a second direction perpendicular to the first direction, and is displaceable in the first direction together with the mass by being separated from the substrate;
a first fixed electrode that is mechanically connected to and electrically insulated from the substrate and faces the first movable electrode at an interval in the first direction;
a pair of second movable electrodes that face each other at an interval in the first direction by being mechanically connected to and electrically insulated from the mass, extend from the mass in the second direction, and are displaceable in the first direction together with the mass by being separated from the substrate; and
a second fixed electrode that is mechanically connected to and electrically insulated from the substrate so as to be interposed between the pair of second movable electrodes, the second fixed electrode being configured to generate an electrostatic force between the pair of second movable electrodes and the second fixed electrode when a voltage is applied to each of the pair of second movable electrodes and the second fixed electrode.

2. The acceleration detection device of claim 1, wherein the pair of second movable electrodes and the second fixed electrode each include a movable side interdigital electrode and a fixed side interdigital electrode extending in the first direction and facing each other in the second direction at an interval.

3. The acceleration detection device of claim 1, further comprising:
an isolation joint that mechanically connects the anchor and the spring and electrically insulates the anchor from the spring, mechanically connects the spring and the mass and electrically insulates the spring from the mass, mechanically connects the mass and the first movable electrode and electrically insulates the mass from the first movable electrode, mechanically connects the substrate and the first fixed electrode and electrically insulates the substrate from the first fixed electrode, mechanically connects the mass and the pair of second movable electrodes and electrically insulates the mass from the pair of second movable electrodes, and mechanically connects the substrate and the second fixed electrode and electrically insulates the substrate from the second fixed electrode.

4. An acceleration sensor comprising:
the acceleration detection device of claim 1;
a resonance frequency adjuster configured to adjust a resonance frequency of a spring-mass system constituted by the spring and the mass by applying a voltage to control the electrostatic force between the pair of second movable electrodes and the second fixed electrode; and
an acceleration calculator configured to calculate an acceleration according to a change in capacitance between the first movable electrode and the first fixed electrode.

5. The acceleration sensor of claim 4, further comprising:
an electrode fixation determiner configured to detect a position of the mass based on a potential of the second fixed electrode when a voltage is applied to the pair of second movable electrodes and determine whether or not the first movable electrode and the first fixed electrode are fixed; and
an electrode fixation releaser configured to, after the electrode fixation determiner determines that the first movable electrode and the first fixed electrode are fixed, release the fixation between the first movable electrode and the first fixed electrode by applying a voltage to control the electrostatic force between the pair of second movable electrodes and the second fixed electrode and displacing the mass in the first direction.

6. The acceleration sensor of claim 4, further comprising:
an offset trimmer configured to correct a zero point of the mass in the first direction when an acceleration is not applied to the mass, by applying a voltage to control the electrostatic force between the pair of second movable electrodes and the second fixed electrode and displacing the mass in the first direction.

7. The acceleration sensor of claim 4, further comprising:
a self-tester configured to, when performing a self-test to diagnose whether or not an acceleration is capable of being calculated, apply a voltage to control the electrostatic force between the pair of second movable electrodes and the second fixed electrode and displace the mass in the first direction.
